(19) United States
(12) Patent Application Publication
(10) Pub. No.: US 2026/0156999 A1
(43) Pub. Date: Jun. 4, 2026

(54) Display Device Including Light Emitting Diode and Method of Fabricating the Same

(71) Applicant: LG Display Co., Ltd., Seoul (KR)

(72) Inventors: Kang-Hyun KIM, Paju-si (KR); Sung-Hwan YOON, Paju-si (KR)

(21) Appl. No.: 19/180,999

(22) Filed: Apr. 16, 2025

(30) Foreign Application Priority Data
Nov. 29, 2024 (KR) 10-2024-0174495

(51) Int. Cl. H10H 29/49; H10H 29/01

(52) U.S. Cl. CPC H10H 29/49; H10H 29/012

(57) ABSTRACT

A display device includes: a display panel; gate lines and data lines in the display panel, the gate lines and the data lines crossing each other to define first, second and third subpixels; a transistor in each of the first, second and third subpixels and connected to the gate lines and the data lines; and first, second and third light emitting diodes in the first, second and third subpixels, respectively, and connected to the transistor, wherein a top surface of each of the first, second and third light emitting diodes includes a first surface under a step difference in a cross-sectional view and a second surface over the step difference in a cross-sectional view, and wherein the first surfaces of the first, second and third light emitting diodes have one of depths different from each other and areas different from each other.

### CROSS-REFERENCE TO RELATED APPLICATION

The present application claims the priority of Republic of Korea Patent Application No. 10-2024-0174495 filed on Nov. 29, 2024, which is hereby incorporated by reference in its entirety.

### BACKGROUND

### Field of the Disclosure

The present disclosure relates to a display device, and more particularly, to a display device including a light emitting diode having a mesa region of different depths and areas.

### Description of the Background

Recently, various flat panel display devices such as a liquid crystal display device (LCD), an organic light emitting diode (OLED) display device and a field emission display (FED) device having excellent properties of a thin profile, a light weight and a low power consumption have been developed and applied to various fields.

Although the OLED display device among the various flat panel display devices has an advantage such that an additional light source is not required, the OLED display device has a disadvantage such that deterioration may occur by an external circumstance due to a property of an organic material vulnerable to moisture and oxygen.

To overcome the disadvantage, a display device using a light emitting diode chip (or a light emitting diode) of an inorganic material has been suggested.

The light emitting diode chip is attached to a display panel after the light emitting diode chip is formed on a growth substrate. To distinguish red, green, and blue light emitting diode chips from each other, the red, green, and blue light emitting diode chips are formed to have elliptical shapes having different long axes and different short axes.

As a resolution increases, a size of the light emitting diode chip decreases. As a result, an exclusivity according to a long axis and a short axis of the light emitting diode chip may be reduced, and the light emitting diode may be broken.

### SUMMARY

Accordingly, the present disclosure is directed to a display device that substantially obviates one or more of the problems due to limitations and disadvantages of the related art.

More specifically, the present disclosure provides a display device including a light emitting diode where a color mixture is prevented or at least reduced and a fabrication process is optimized by changing a depth or an area of a mesa region.

Further, the present disclosure is to provide a display device including a light emitting diode applicable to a high resolution by forming a mesa region with different depths or different areas and a method of fabricating the display device.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a display panel; a plurality of gate lines and a plurality of data lines in the display panel, the plurality of gate lines and the plurality of data lines crossing each other to define first, second and third subpixels; a transistor in each of the first, second and third subpixels and connected to the plurality of gate lines and the plurality of data lines; and first, second and third light emitting diodes in the first, second and third subpixels, respectively, and connected to the transistor, wherein a top surface of each of the first, second and third light emitting diodes includes a first surface under a step difference in a cross-sectional view and a second surface over the step difference in a cross-sectional view, and wherein the first surfaces of the first, second and third light emitting diodes have one of depths different from each other and areas different from each other.

In another embodiment, a method of fabricating a display device includes: assembling first, second and third light emitting diodes in first, second and third assembly grooves, respectively, of an assembly substrate; and transferring the first, second and third light emitting diodes to a display panel by disposing the assembly substrate having the first, second and third light emitting diodes over the display panel, wherein a top surface of each of the first, second and third light emitting diodes includes a first surface under a step difference in a cross-sectional view and a second surface over the step difference in a cross-sectional view, wherein the first surfaces of the first, second and third light emitting diodes have one of depths different from each other and areas different from each other, and wherein the first, second and third assembly grooves have first, second and third protruding portions, respectively, corresponding to the first surfaces of the first, second and third light emitting diodes

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing a display device according to a first embodiment of the present disclosure;

FIG. 2 is a circuit diagram showing a subpixel of a display device according to a first embodiment of the present disclosure;

FIG. 3 is a cross-sectional view showing a subpixel of a display panel of a display device according to a first embodiment of the present disclosure;

FIG. 4 is a view showing an assembly substrate of a light emitting diode of a display device according to a first embodiment of the present disclosure;

FIG. 5 is a magnified view of a portion A of FIG. 4 according to an embodiment of the present disclosure;

FIG. 6A is a cross-sectional view showing a first assembly groove of an assembly substrate and a first light emitting diode for a display device according to a first embodiment of the present disclosure;

FIG. 6B is a cross-sectional view showing a first assembly groove of an assembly substrate and a second light emitting diode for a display device according to a first embodiment of the present disclosure;

FIG. 6C is a cross-sectional view showing a first assembly groove of an assembly substrate and a third light emitting diode for a display device according to a first embodiment of the present disclosure;

FIG. 7A is a cross-sectional view showing a second assembly groove of an assembly substrate and a second light emitting diode for a display device according to a first embodiment of the present disclosure;

FIG. 7B is a cross-sectional view showing a second assembly groove of an assembly substrate and a first light emitting diode for a display device according to a first embodiment of the present disclosure;

FIG. 7C is a cross-sectional view showing a second assembly groove of an assembly substrate and a third light emitting diode for a display device according to a first embodiment of the present disclosure;

FIG. 8A is a cross-sectional view showing a third assembly groove of an assembly substrate and a third light emitting diode for a display device according to a first embodiment of the present disclosure;

FIG. 8B is a cross-sectional view showing a third assembly groove of an assembly substrate and a first light emitting diode for a display device according to a first embodiment of the present disclosure;

FIG. 8C is a cross-sectional view showing a third assembly groove of an assembly substrate and a second light emitting diode for a display device according to a first embodiment of the present disclosure;

FIG. 9A is a perspective view showing a first assembly groove of an assembly substrate and a first light emitting diode for a display device according to a second embodiment of the present disclosure;

FIG. 9B is a plan view showing a first assembly groove of an assembly substrate and a first light emitting diode for a display device according to a second embodiment of the present disclosure;

FIG. 9C is a plan view showing a first assembly groove of an assembly substrate and a second light emitting diode for a display device according to a second embodiment of the present disclosure;

FIG. 9D is a plan view showing a first assembly groove of an assembly substrate and a third light emitting diode for a display device according to a second embodiment of the present disclosure;

FIG. 10A is a perspective view showing a second assembly groove of an assembly substrate and a second light emitting diode for a display device according to a second embodiment of the present disclosure;

FIG. 10B is a plan view showing a second assembly groove of an assembly substrate and a second light emitting diode for a display device according to a second embodiment of the present disclosure;

FIG. 10C is a plan view showing a second assembly groove of an assembly substrate and a first light emitting diode for a display device according to a second embodiment of the present disclosure;

FIG. 10D is a plan view showing a second assembly groove of an assembly substrate and a third light emitting diode for a display device according to a second embodiment of the present disclosure;

FIG. 11A is a perspective view showing a third assembly groove of an assembly substrate and a third light emitting diode for a display device according to a second embodiment of the present disclosure;

FIG. 11B is a plan view showing a third assembly groove of an assembly substrate and a third light emitting diode for a display device according to a second embodiment of the present disclosure;

FIG. 11C is a plan view showing a third assembly groove of an assembly substrate and a first light emitting diode for a display device according to a second embodiment of the present disclosure;

FIG. 11D is a plan view showing a third assembly groove of an assembly substrate and a second light emitting diode for a display device according to a second embodiment of the present disclosure.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module, and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

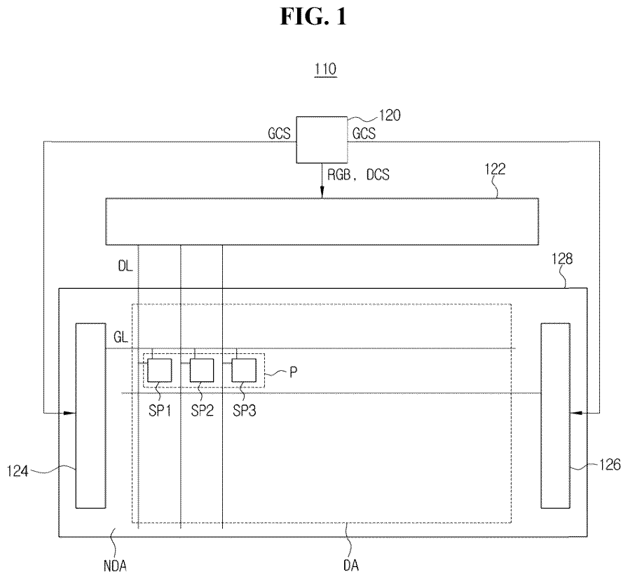

FIG. 1 is a view showing a display device according to a first embodiment of the present disclosure. Although the display device may be an organic light emitting diode (OLED) display device, it is not limited thereto. For example, the display device may be a micro light emitting diode (LED) display device or a mini light emitting diode (LED) display device.

In FIG. 1, a display device 110 according to a first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates image data RGB, a data control signal DCS and a gate control signal GCS using an image signal and a plurality of timing signals including a data enable signal, a horizontal synchronization signal, a vertical synchronization signal and a clock signal transmitted from an external system such as a graphic card or a television system. The timing controlling unit 120 transmits the image data RGB and the data control signal DCS to the data driving unit 122 and transmits the gate control signal GCS to the first and second gate driving units 124 and 126.

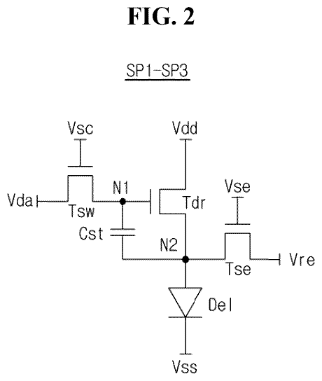

The data driving unit 122 generates a data signal (a data voltage) Vda (of FIG. 2) using the image data RGB and the data control signal DCS transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal GCS transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. For displaying an image, the display panel 128 includes a plurality of pixels P, a plurality of gate lines GL and a plurality of data lines DL in the display area DA.

Each of the plurality of pixels P includes first, second and third subpixels SP1, SP2 and SP3, and the gate line GL and the data line DL cross each other to define the first, second and third subpixels SP1, SP2 and SP3. Each of the first, second, and third subpixels SP1, SP2, and SP3 is connected to the gate line GL and the data line DL. For example, the first, second and third subpixels SP1, SP2 and SP3 may correspond to first, second and third colors, respectively, and the first, second and third colors may be red, green and blue colors, respectively.

Each of the first, second, and third subpixels SP1, SP2, and SP3 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

FIG. 2 is a circuit diagram showing a subpixel of a display device according to a first embodiment of the present disclosure.

In FIG. 2, each of the first, second, and third subpixels SP1, SP2, and SP3 of the display panel 128 of the display device 110 according to a first embodiment of the present disclosure includes a switching transistor Tsw, a driving transistor Tdr, a sensing transistor Tse, a storage capacitor Cst, and a light emitting diode Del.

Although each of the first, second and third subpixels SP1, SP2 and SP3 has a 3T1C structure having three transistors and one storage capacitor in the first embodiment of FIG. 2, each of the first, second and third subpixels SP1, SP2 and SP3 may have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr and the sensing transistor Tse may have a negative type in the first embodiment of FIG. 2, at least one of the switching transistor Tsw, the driving transistor Tdr and the sensing transistor Tse may have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N3 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vdata supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode Del constitute the second node N2.

The light emitting diode Del may display an image having a luminance corresponding to the image data RGB according to a driving of subpixel circuits of the first, second and third subpixels SP1, SP2 and SP3.

A cross-sectional structure of each subpixel SP1, SP2 and SP3 of the display panel 128 of the display device 110 will be illustrated with reference to a drawing.

FIG. 3 is a cross-sectional view showing a subpixel of a display panel of a display device according to a first embodiment of the present disclosure.

In FIG. 3, a light shielding pattern 132 is disposed in each of the first, second and third subpixels SP1, SP2, and SP3 on a substrate 130, and a first buffer layer 134 is disposed on the light shielding pattern 132 over the entire substrate 130.

The light shielding pattern 132 may block a light incident from a lower portion of the substrate 130. For example, the light shielding pattern 132 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

The first buffer layer 134 may block a moisture or an oxygen permeating from an exterior. For example, the first buffer layer 134 may have a single layer or a multiple layer of an inorganic insulating material such as silicon oxide (SiO2) and silicon nitride (SiNx).

A semiconductor layer 136 is disposed on the first buffer layer 134 corresponding to the light shielding pattern 132, and a gate insulating layer 138 is disposed on the semiconductor layer 136 over the entire substrate 130.

The semiconductor layer 136 includes a channel region not doped with an impurity at a central portion thereof and source and drain regions doped with an impurity at both side portions of the channel region. For example, the semiconductor layer 136 may include a polycrystalline semiconductor material such as polycrystalline silicon or an oxide semiconductor material such as indium gallium zinc oxide (IGZO), zinc oxide (ZnO), tin oxide (SnO2), copper oxide (Cu2O), nickel oxide (NiO), indium tin zinc oxide (ITZO) and indium aluminum zinc oxide (IAZO).

For example, the gate insulating layer 138 may have a single layer or a multiple layer of an inorganic insulating material such as silicon oxide (SiO2) and silicon nitride (SiNx).

A gate electrode 140 is disposed on the gate insulating layer 138 corresponding to the channel region of the semiconductor layer 136, a first capacitor electrode 142 separated from the gate electrode 140 is disposed on the gate insulating layer 138, and a first interlayer insulating layer 144 is disposed on the gate electrode 140 and the first capacitor electrode 142.

The gate electrode 140 and the first capacitor electrode 142 may have the same layer and the same material as each other. For example, the gate electrode 140 and the first capacitor electrode 142 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 may have a single layer or a multiple layer of an inorganic insulating material such as silicon oxide (SiO2) and silicon nitride (SiNx).

A second capacitor electrode 146 is disposed on the first interlayer insulating layer 144 corresponding to the first capacitor electrode 142, and a second interlayer insulating layer 148 is disposed on the second capacitor electrode 146 over the entire substrate 130.

For example, the second capacitor electrode 146 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the second interlayer insulating layer 148 may have a single layer or a multiple layer of an inorganic insulating material such as silicon oxide (SiO2) and silicon nitride (SiNx).

The first capacitor electrode 142, the first interlayer insulating layer 144, and the second capacitor electrode 146 may constitute the storage capacitor Cst.

A source electrode 150 and a drain electrode 152 that are spaced apart from each other are disposed on the second interlayer insulating layer 148, and a first planarizing layer 154 is disposed on the source electrode 150 and the drain electrode 152 over the entire substrate 130.

The source electrode 150 and the drain electrode 152 are connected to the source region and the drain region, respectively, of the semiconductor layer 136 through contact holes in the second interlayer insulating layer 148, the first interlayer insulating layer 144 and the gate insulating layer 138, and the drain electrode 152 is connected to the light shielding pattern 132 through a contact hole in the second interlayer insulating layer 148, the first interlayer insulating layer 144, the gate insulating layer 138 and the first buffer layer 134.

The source electrode 150 and the drain electrode 152 may have the same layer and the same material as each other. For example, the source electrode 150 and the drain electrode 152 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first planarizing layer 154 may have a single layer or a multiple layer of an organic insulating material such as photoacryl and benzocyclobutene (BCB).

The semiconductor layer 136, the gate electrode 140, the source electrode 150 and the drain electrode 152 may constitute the driving transistor Tdr.

A connecting electrode 156 is disposed on the first planarizing layer 154 corresponding to the source electrode 150, a power line 158 spaced apart from the connecting electrode 156 is disposed on the first planarizing layer 154, and an adhesive layer 160 is disposed on the connecting electrode 156 and the power line 158 over the entire substrate 130.

The connecting electrode 156 is connected to the source electrode 150 through a contact hole in the first planarizing layer 154, and the connecting electrode 156 and the power line 158 may have the same layer and the same material as each other.

For example, the connecting electrode 156 and the power line 158 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the power line 158 may supply the low level signal Vss.

A first semiconductor layer 162 is disposed on the adhesive layer 160 corresponding to the connecting electrode 156, an active layer 164, a second semiconductor layer 166 and a second electrode 170 are sequentially disposed on a first side portion of the first semiconductor layer 162, and a first electrode 168 is disposed on a second side portion of the first semiconductor layer 162.

The first semiconductor layer 162 supplies an electron to the active layer 164, the second semiconductor layer 166 supplies a hole to the active layer 164, and the active layer 164 generates a light using an electron and a hole.

For example, the first semiconductor layer 162 may include a negative type gallium nitride (n-GaN), the second semiconductor layer 166 may include a positive type gallium nitride (p-GaN), and the active layer 164 may include a multi quantum well (MQW).

For example, the first electrode 168 may be a cathode, and the second electrode 170 may be an anode.

The first semiconductor layer 162, the active layer 164, the second semiconductor layer 166, the first electrode 168, and the second electrode 170 may constitute the light emitting diode Del (or light emitting diode chip).

A second planarizing layer 172 is disposed on the first and second electrodes 168 and 170 over the entire substrate 130, and first and second connecting lines 174 and 176 that are spaced apart from each other are disposed on the second planarizing layer 172 corresponding to the light emitting diode Del.

For example, the second planarizing layer 172 may have a single layer or a multiple layer of an organic insulating material such as photoacryl and benzocyclobutene (BCB).

The first connecting line 174 is connected to the power line 158 through a contact hole in the adhesive layer 160 and the second planarizing layer 172 and connected to the first electrode 168 through a contact hole in the second planarizing layer 172.

The second connecting line 176 is connected to the connecting electrode 156 through a contact hole in the adhesive layer 160 and the second planarizing layer 172 and connected to the second electrode 170 through a contact hole in the second planarizing layer 172.

For example, the first and second connecting lines 174 and 176 may include a metallic material such as one of molybdenum (Mo), aluminum (Al), chromium (Cr), gold (Au), titanium (Ti), nickel (Ni), neodymium (Nd) and copper (Cu) or a transparent conductive material such as indium tin oxide (ITO) and indium zinc oxide (IZO).

In the first embodiment, the first and second connecting lines 174 and 176 are exemplarily disposed on the second planarizing layer 172 to be connected to the first and second electrodes 168 and 170, respectively, through the contact holes in the second planarizing layer 172. In another embodiment, after the second planarizing layer 172 may be removed through an ashing step till the first electrode 168 is exposed, the first connecting line 174 connected to the first electrode 168 may be formed and a third planarizing layer may be coated on the first connecting line 174. Next, after the third planarizing layer may be removed through an ashing step till the second electrode 168 is exposed, the second connecting line 176 connected to the second electrode 168 may be formed.

An encapsulating layer 178 is disposed on the first and second connecting lines 174 and 176 over the entire substrate 130.

The encapsulating layer 178 prevents or at least reduces a permeation of a particle such as an oxygen or a moisture.

For example, the encapsulating layer 178 may have a single layer or a multiple layer of an inorganic insulating material such as silicon oxide (SiO2) and silicon nitride (SiNx).

The light emitting diode Del of the display device 110 may be attached to the substrate 130 through a self-assembly technology.

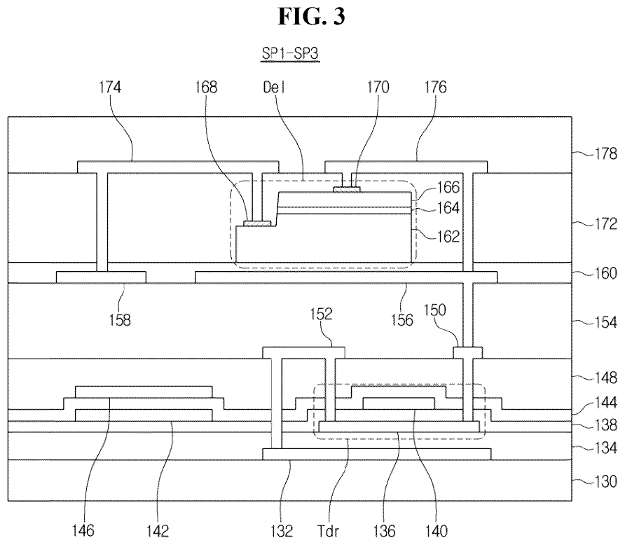

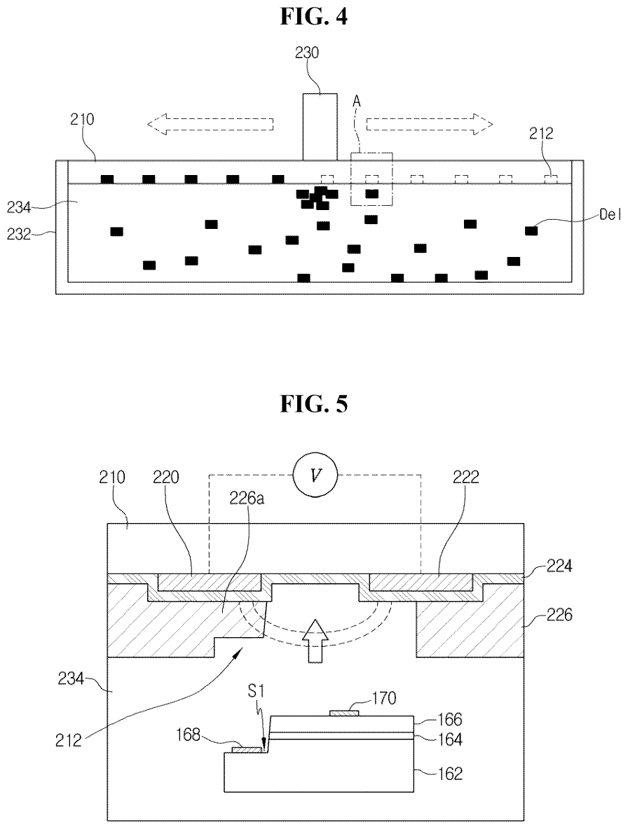

FIG. 4 is a view showing an assembly substrate of a light emitting diode of a display device according to a first embodiment of the present disclosure, and FIG. 5 is a magnified view of a portion A of FIG. 4 according to one embodiment.

In FIG. 4, an assembly substrate 210 having a plurality of assembly grooves 212 is disposed over a chamber 232, a magnetic rod 230 generating a magnetic field is disposed over the assembly substrate 210, and a fluid 234 including a plurality of light emitting diodes (LEDs) Del is disposed in the chamber 232.

The magnetic rod 230 may move along up, down, left and right directions and rotate, and the plurality of LEDs Del may be formed on a growth substrate and then be detached from the growth substrate.

For example, the fluid 234 may include a water such as a deionized water.

The plurality of LEDs Del moves toward the assembly substrate 210 in the fluid 234 by the magnetic field of the magnetic rod 230, and each of the LEDs Del may have a magnetic layer.

For example, the magnetic layer may include a metal having a magnetic property such as nickel (Ni) and may be disposed on a top surface or a side surface of the first semiconductor layer 162 or the second semiconductor layer 166 or in at least one of first and second electrodes 168 and 170 of the LED Del.

In FIG. 5, first and second assembly electrodes 220 and 222 spaced apart from each other are disposed on a lower surface of the assembly substrate 210, and an insulating layer 224 is disposed on the first and second assembly electrodes 220 and 222 over the entire assembly substrate 210.

For example, the first and second assembly electrodes 220 and 222 may include a transparent conductive material or a metallic material, and the insulating layer 224 may have a single layer or a multiple layer of an inorganic insulating material or an organic insulating material.

A sidewall 226 is disposed on the insulating layer 224 corresponding to the first and second assembly electrodes 220 and 222. The sidewall 226 partially overlaps each of the first and second assembly electrodes 220 and 222, and a space surrounded by the sidewall 212 constitutes the assembly groove 212.

When an alternating current (AC) voltage is applied to the first and second assembly electrodes 220 and 222, an electric field is generated between the first and second assembly electrodes 220 and 222, and the LED Del adjacent to the plurality of assembly grooves 212 among the plurality of LEDs Del in the fluid 234 may be assembled to the assembly groove 212 by a dielectric phoretic force due to the electric field generated between the first and second assembly electrodes 220 and 222.

The LED Del may be assembled to the assembly substrate 210 such that a first surface S1 having the first electrode 168 and a second surface S2 having the second electrode 170 face the assembly groove 212.

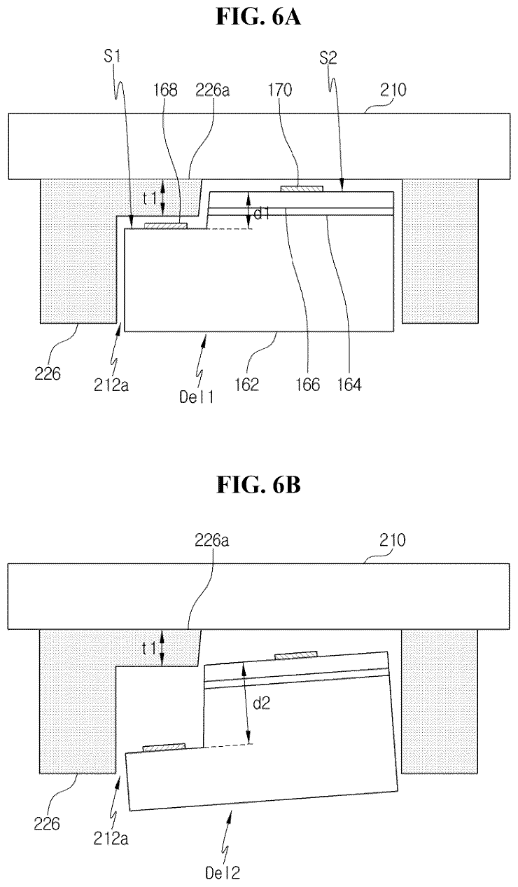

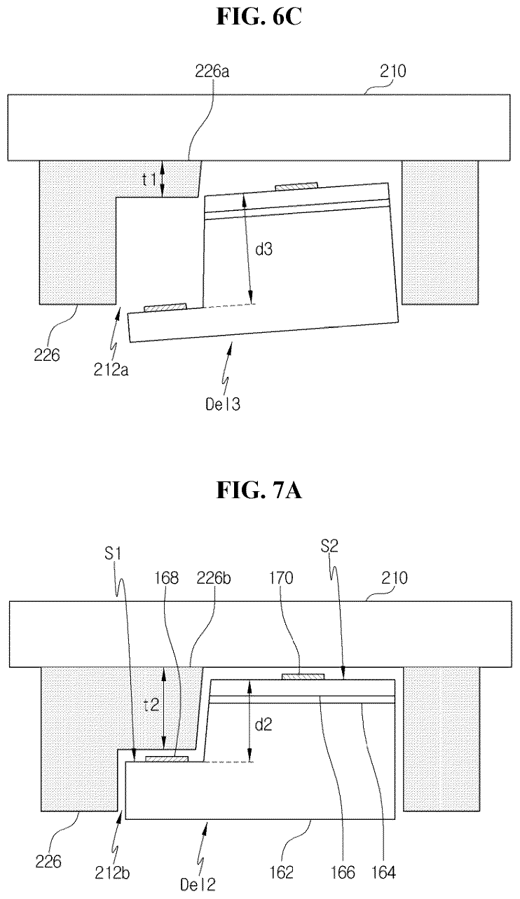

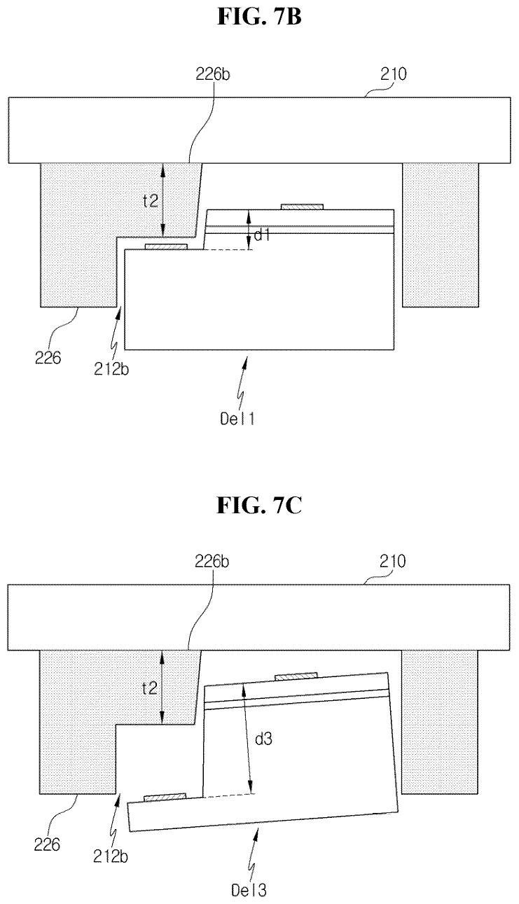

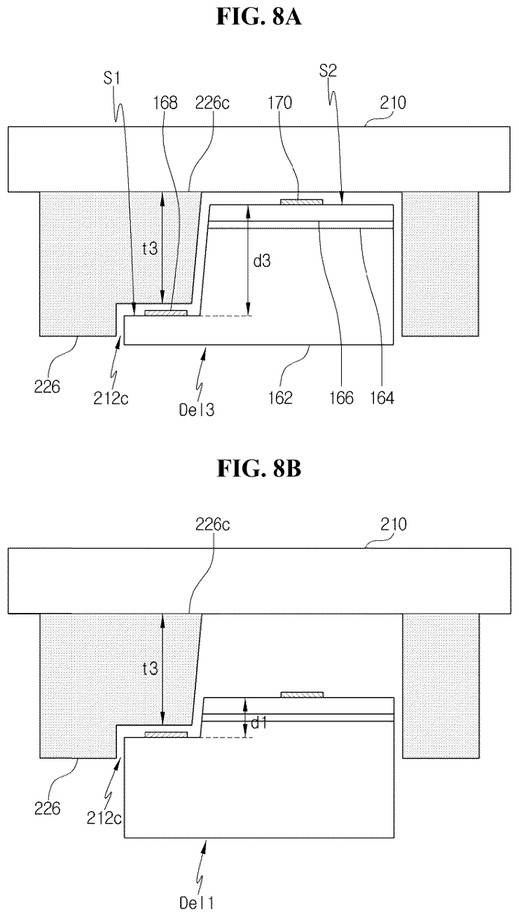

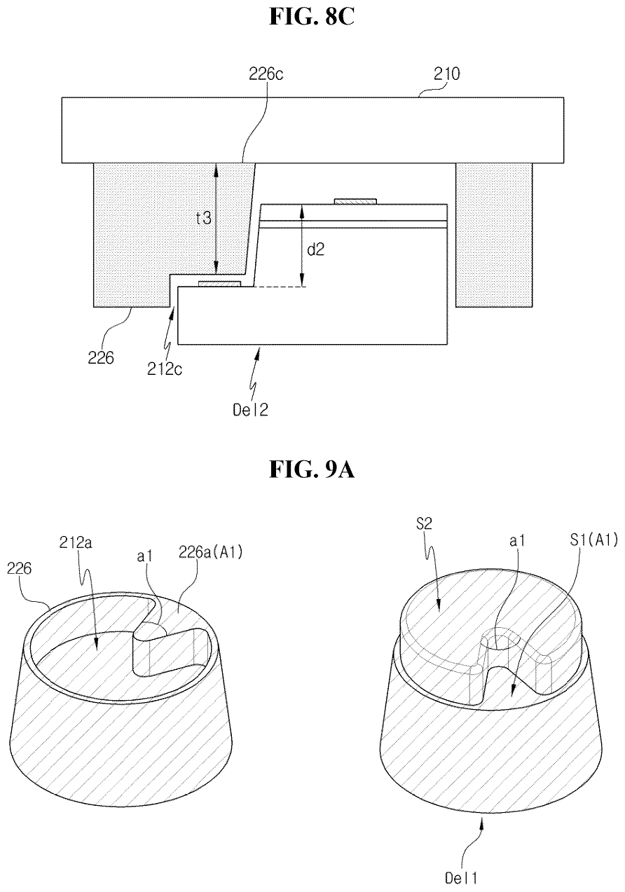

The plurality of LEDs Del include first, second, and third LEDs Del1 (of FIG. 6A), Del2 (of FIG. 7A) and Del3 (of FIG. 8A) emitting first, second and third colored lights, respectively, and having first, second and third depths d1 (of FIG. 6A), d2 (of FIG. 7A) and d3 (of FIG. 8A) from the second surface S2 to the first surface S1. The plurality of assembly grooves 212 include first, second, and third assembly grooves 212a (of FIGS. 6A), 212b (of FIGS. 7A) and 212c (of FIG. 8A) corresponding to the first, second and third depths d1, d2 and d3, respectively, of the first, second and third LEDs Del1, Del2 and Del3.

For example, the first, second, and third colored lights may correspond to red, green, and blue light, respectively.

The first and second surfaces S1 and S2 of the first, second, and third LEDs Del1, Del2 and Del3 are formed to have different depths, and first, second, and third protruding portions 226a (of FIGS. 6A), 226b (of FIGS. 7A) and 226c (of FIG. 8A) of the first, second, and third assembly grooves 212a, 212b and 212c of the assembly substrate 210 are formed to have different thicknesses. As a result, a distinguishability (exclusivity) between the first, second and third LEDs Del1, Del2 and Del3 is obtained.

When the first, second and third LEDs Del1, Del2 and Del3 are properly assembled to the first, second, and third assembly grooves 212a, 212b and 212c, respectively, an electric force applied to the first, second, and third LEDs Del1, Del2 and Del3 by the electric field of the first and second assembly electrodes 220 and 222 becomes greater than a magnetic force applied to the first, second, and third LEDs Del1, Del2 and Del3 by the magnetic field of the magnetic rod 230 so that the first, second, and third LEDs Del1, Del2 and Del3 cannot escape from and can be stably fixed to the first, second and third assembly grooves 212a, 212b and 212c, respectively.

When the first, second, and third LEDs Del1, Del2 and Del3 are not properly assembled to the first, second, and third assembly grooves 212a, 212b and 212c, respectively, the magnetic force applied to the first, second and third LEDs Del1, Del2 and Del3 by the magnetic field of the magnetic rod 230 becomes greater than the electric force applied to the first, second, and third LEDs Del1, Del2 and Del3 by the electric field of the first and second assembly electrodes 220 and 222 so that the first, second, and third LEDs Del1, Del2 and Del3 can escape from the first, second, and third assembly grooves 212a, 212b and 212c, respectively. The first, second, and third LEDs Del1, Del2 and Del3 having escaped from the first, second, and third assembly grooves 212a, 212b and 212c may float in the fluid 234 till the first, second, and third LEDs Del1, Del2 and Del3 are properly assembled to the first, second and third assembly grooves 212a, 212b and 212c, respectively.

When the plurality of LEDs Del are properly assembled to the plurality of assembly grooves 212 of the assembly substrate 210, the assembly substrate 210 is disposed on the adhesive layer 160 of the substrate 130 of the display panel 128, and the plurality of LEDs Del of the plurality of assembly grooves 212 are transferred and attached to the adhesive layer 160 of each subpixel SP1, SP2 and SP3 without using an additional transfer substrate.

In another embodiment, a transfer step may be omitted using the substrate 130 having the driving transistor Tdr as the assembly substrate 210.

Dispositions and shapes of the assembly substrate 210 and the plurality of LEDs Del will be illustrated with reference to drawings.

FIG. 6A is a cross-sectional view showing a first assembly groove of an assembly substrate and a first light emitting diode for a display device according to a first embodiment of the present disclosure, FIG. 6B is a cross-sectional view showing a first assembly groove of an assembly substrate and a second light emitting diode for a display device according to a first embodiment of the present disclosure, and FIG. 6C is a cross-sectional view showing a first assembly groove of an assembly substrate and a third light emitting diode for a display device according to a first embodiment of the present disclosure. FIG. 7A is a cross-sectional view showing a second assembly groove of an assembly substrate and a second light emitting diode for a display device according to a first embodiment of the present disclosure, FIG. 7B is a cross-sectional view showing a second assembly groove of an assembly substrate and a first light emitting diode for a display device according to a first embodiment of the present disclosure, and FIG. 7C is a cross-sectional view showing a second assembly groove of an assembly substrate and a third light emitting diode for a display device according to a first embodiment of the present disclosure. FIG. 8A is a cross-sectional view showing a third assembly groove of an assembly substrate and a third light emitting diode for a display device according to a first embodiment of the present disclosure, FIG. 8B is a cross-sectional view showing a third assembly groove of an assembly substrate and a first light emitting diode for a display device according to a first embodiment of the present disclosure, and FIG. 8C is a cross-sectional view showing a third assembly groove of an assembly substrate and a second light emitting diode for a display device according to a first embodiment of the present disclosure.

For illustration's convenience, the first and second assembly electrodes 220 and 222 and the insulating layer 224 of the assembly substrate 210 are omitted in FIGS. 6A to 8C.

In FIG. 6A, a top surface of the first LED Del1 in the first subpixel SP1 of the display device 110 according to a first embodiment of the present disclosure includes the first surface S1, referred to as a mesa region, having the first electrode 168 and the second surface S2 having the second electrode 170 and disposed higher than the first surface S1.

The first assembly groove 212a of the assembly substrate 210 is defined as a space surrounded by the sidewall 226 and has a shape corresponding to the first and second surfaces S1 and S2. The sidewall 226 of the first assembly groove 212a has the first protruding portion 226a extending from an inner surface thereof and corresponding to a step difference between the first and second surfaces S1 and S2 of the first LED Del1.

The first LED Del1 has one of a polygon shape, an ellipse shape, or a circle shape in a plan view. The first surface S1 of the first LED Del1 is disposed under the step difference in a cross-sectional view, and the second surface S2 of the first LED Del1 is disposed over the step difference in a cross-sectional view. The first and second surfaces S1 and S2 have the step difference of the first depth d1.

The first protruding portion 226a protruding toward the first assembly groove 212a has a first thickness t1 substantially the same as the first depth d1.

As a result, the first LED Del1 is stably assembled to the first assembly groove 212a.

In FIG. 7A, a top surface of the second LED Del2 in the second subpixel SP2 of the display device 110 according to a first embodiment of the present disclosure includes the first surface S1, referred to as a mesa region, having the first electrode 168 and the second surface S2 having the second electrode 170 and disposed higher than the first surface S1.

The second assembly groove 212b of the assembly substrate 210 is defined as a space surrounded by the sidewall 226 and has a shape corresponding to the first and second surfaces S1 and S2. The sidewall 226 of the second assembly groove 212b has the second protruding portion 226b extending from an inner surface thereof and corresponding to a step difference between the first and second surfaces S1 and S2 of the second LED Del2.

The second LED Del2 has one of a polygon shape, an ellipse shape, or a circle shape in a plan view. The first surface S1 of the second LED Del2 is disposed under the step difference in a cross-sectional view, and the second surface S2 of the second LED Del2 is disposed over the step difference in a cross-sectional view. The first and second surfaces S1 and S2 have the step difference of the second depth d2 greater than the first depth d1.

The second protruding portion 226b protruding toward the second assembly groove 212b has a second thickness t2 substantially the same as the second depth d2.

As a result, the second LED Del2 is stably assembled to the second assembly groove 212b.

In FIG. 8A, a top surface of the third LED Del3 in the third subpixel SP3 of the display device 110 according to a first embodiment of the present disclosure includes the first surface S1, referred to as a mesa region, having the first electrode 168 and the second surface S2 having the second electrode 170 and disposed higher than the first surface S1.

The third assembly groove 212c of the assembly substrate 210 is defined as a space surrounded by the sidewall 226 and has a shape corresponding to the first and second surfaces S1 and S2. The sidewall 226 of the third assembly groove 212c has the third protruding portion 226c extending from an inner surface thereof and corresponding to a step difference between the first and second surfaces S1 and S2 of the third LED Del3.

The third LED Del3 has one of a polygon shape, an ellipse shape, or a circle shape in a plan view. The first surface S1 of the third LED Del3 is disposed under the step difference in a cross-sectional view, and the second surface S2 of the third LED Del3 is disposed over the step difference in a cross-sectional view. The first and second surfaces S1 and S2 have the step difference of the third depth d3 greater than the second depth d2.

The third protruding portion 226c protruding toward the third assembly groove 212c has a third thickness t3 substantially the same as the third depth d3.

As a result, the third LED Del3 is stably assembled to the third assembly groove 212c.

In FIGS. 6B and 6C, when the second and third LEDs Del2 and Del3 having the second and third depths d2 and d3 greater than the first thickness t1 of the first assembly groove 212a are inserted into the first assembly groove 212a, the magnetic force becomes greater than the electric force due to an abnormal assembly. As a result, the second and third LEDs Del2 and Del3 are not assembled to and easily escape from the first assembly groove 212a.

In FIG. 7B, when the first LED Del1 having the first depth d1 that is smaller than the second thickness t2 of the second assembly groove 212b is inserted into the second assembly groove 212b, the first LED Del1 does not contact the second assembly groove 212b due to the step difference. As a result, the first LED Del1 is not assembled to and easily escapes from the second assembly groove 212b.

In FIG. 7C, when the third LED Del3 having the third depth d3 that is greater than the second thickness t2 of the second assembly groove 212b is inserted into the second assembly groove 212b, the magnetic force becomes greater than the electric force due to an abnormal assembly. As a result, the third LED Del3 is not assembled to and easily escapes from the second assembly groove 212b.

In FIGS. 8B and 8C, when the first and second LEDs Del1 and Del2 having the first and second depths d1 and d2 that are smaller than the third thickness t3 of the third assembly groove 212c are inserted into the third assembly groove 212c, the first and second LEDs Del1 and Del2 do not contact the third assembly groove 212c due to the step difference. As a result, the first and second LEDs Del1 and Del2 are not assembled to and easily escape from the third assembly groove 212c.

In the first embodiment, when a dry etching step has a process margin of about ±5%, the dry etching step for forming the sidewall 226 of a thickness of about 5 μm has a first process margin of about ±0.25 μm, and the dry etching step for forming the mesa region of the LED Del of the depth of about 2 μm has a second process margin of about ±0.1 μm. Accordingly, the first, second and third depths d1, d2, and d3 for a sequential color mixture assembly of the LEDs Del may be determined to have a difference equal to or greater than about 0.35 μm, which is a sum of the first and second process margins.

For example, the first, second and third depths d1, d2, and d3 may be about 1.5 μm, about 2.0 μm and about 2.5 μm, respectively.

In the display device 110 according to a first embodiment of the present disclosure, the first surfaces (mesa region) S1 of the first, second and third LEDs Del1, Del2 and Del3 are formed to have the first, second and third depths d1, d2 and d3 different from each other, and the first, second and third protruding portions 226a, 226b and 226c of the first, second and third assembly grooves 212a, 212b and 212c are formed to have the first, second and third thicknesses t1, t2 and t3 different from each other and corresponding to the first, second and third depths d1, d2 and d3. As a result, an exclusivity (distinguishability) between the first, second and third LEDs Del1, Del2 and Del3 is improved, and a color mixture due to an abnormal assembly of the first, second and third LEDs Del1, Del2, and Del3 is prevented to obtain a high resolution.

Although the first, second and third colors of the first, second, and third LEDs Del1, Del2, and Del3 exemplarily correspond to red, green, and blue, respectively, in the first embodiment, the first, second, and third colors may correspond to green, blue, and red, respectively, or blue, red, and green, respectively, in another embodiment. Alternatively, the first, second and third colors may correspond to different three colors, respectively, in another embodiment.

In another embodiment, the mesa regions of the first, second and third colors of the first, second and third LEDs Del1, Del2 and Del3 may have different areas.

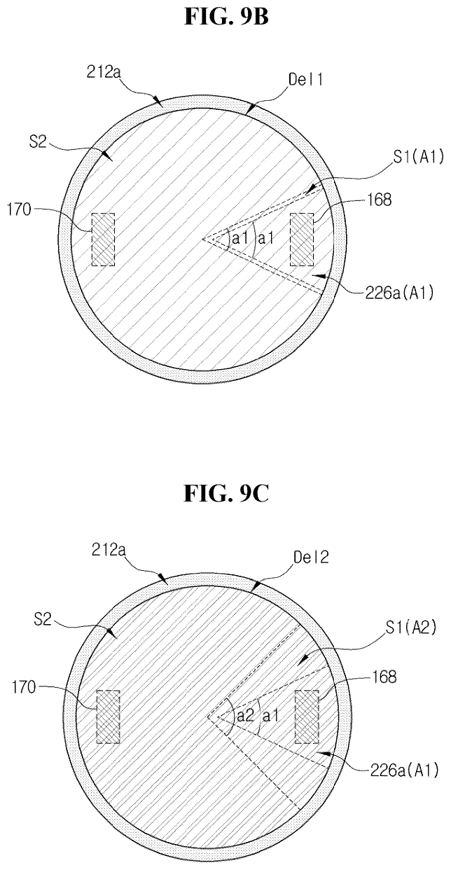

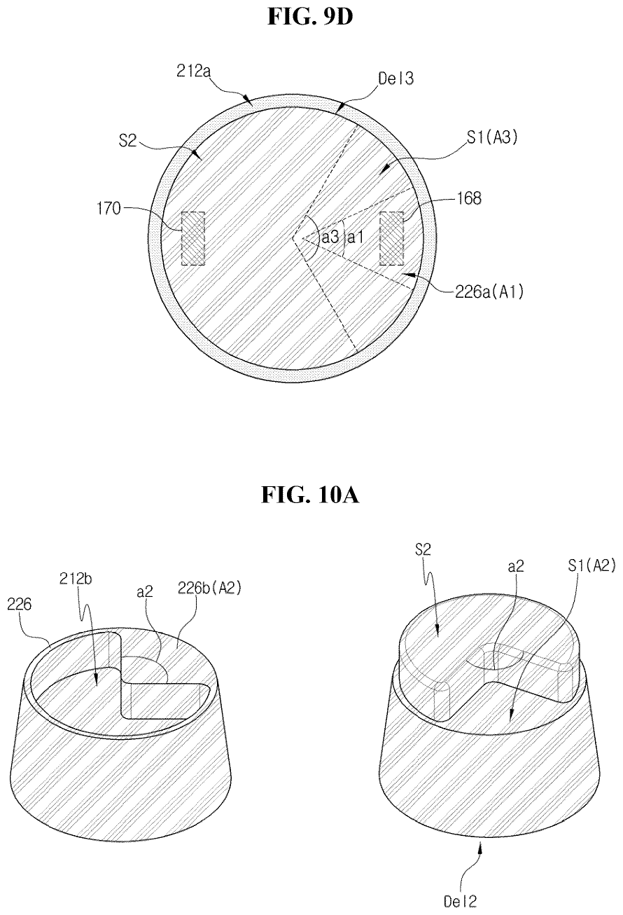

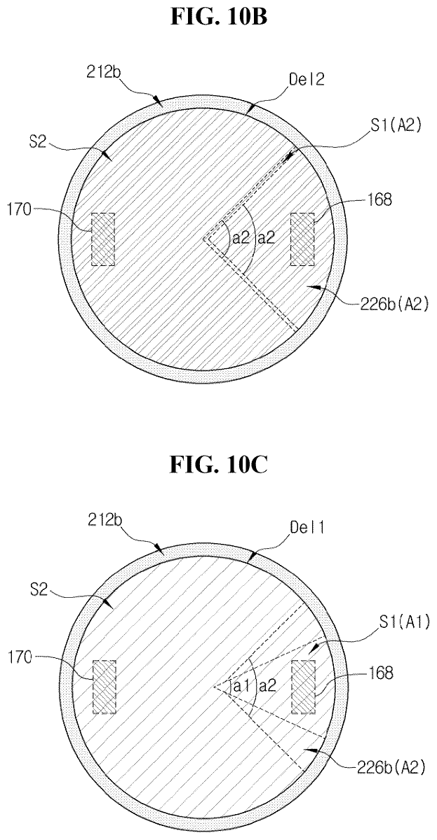

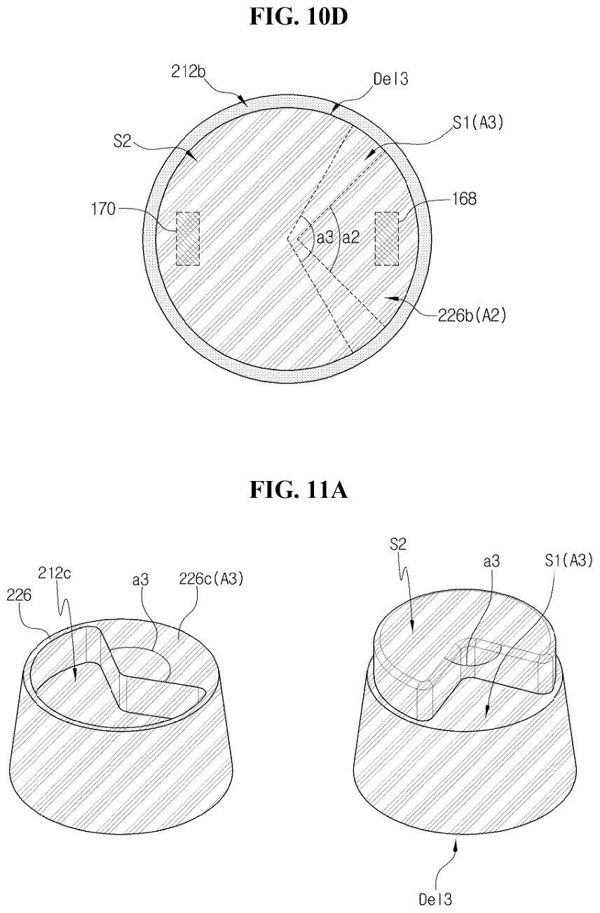

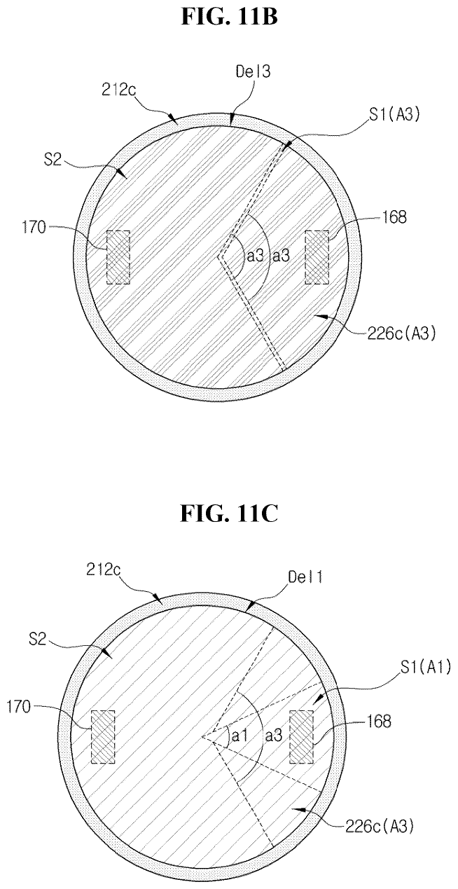

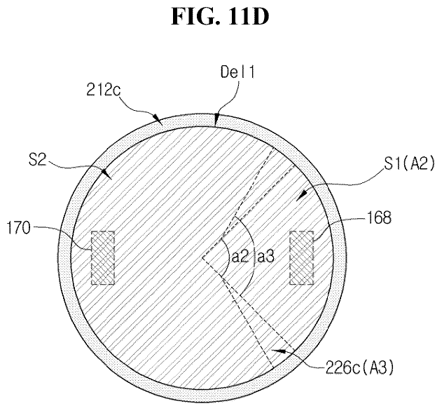

FIG. 9A is a perspective view showing a first assembly groove of an assembly substrate and a first light emitting diode for a display device according to a second embodiment of the present disclosure, FIG. 9B is a plan view showing a first assembly groove of an assembly substrate and a first light emitting diode for a display device according to a second embodiment of the present disclosure, FIG. 9C is a plan view showing a first assembly groove of an assembly substrate and a second light emitting diode for a display device according to a second embodiment of the present disclosure, and FIG. 9D is a plan view showing a first assembly groove of an assembly substrate and a third light emitting diode for a display device according to a second embodiment of the present disclosure. FIG. 10A is a perspective view showing a second assembly groove of an assembly substrate and a second light emitting diode for a display device according to a second embodiment of the present disclosure, FIG. 10B is a plan view showing a second assembly groove of an assembly substrate and a second light emitting diode for a display device according to a second embodiment of the present disclosure, FIG. 10C is a plan view showing a second assembly groove of an assembly substrate and a first light emitting diode for a display device according to a second embodiment of the present disclosure, and FIG. 10D is a plan view showing a second assembly groove of an assembly substrate and a third light emitting diode for a display device according to a second embodiment of the present disclosure. FIG. 11A is a perspective view showing a third assembly groove of an assembly substrate and a third light emitting diode for a display device according to a second embodiment of the present disclosure, FIG. 11B is a plan view showing a third assembly groove of an assembly substrate and a third light emitting diode for a display device according to a second embodiment of the present disclosure, FIG. 11C is a plan view showing a third assembly groove of an assembly substrate and a first light emitting diode for a display device according to a second embodiment of the present disclosure, and FIG. 11D is a plan view showing a third assembly groove of an assembly substrate and a second light emitting diode for a display device according to a second embodiment of the present disclosure.

For illustration's convenience, the first and second assembly electrodes 220 and 222 and the insulating layer 224 of the assembly substrate 210 are omitted in FIGS. 9A to 11D.

In FIGS. 9A and 9B, a top surface of a first LED Del1 in a first subpixel of a display device according to a second embodiment of the present disclosure includes a first surface S1, referred to as a mesa region, having a first electrode 168 and a second surface S2 having a second electrode 170 and disposed higher than the first surface S1.

A first assembly groove 212a of the assembly substrate 210 is defined as a space surrounded by a sidewall 226 and has a shape corresponding to the first and second surfaces S1 and S2 of the first LED Del1. The sidewall 226 of the first assembly groove 212a has a first protruding portion 226a extending from an inner surface thereof and corresponding to the first surface S1 and a step difference between the first and second surfaces S1 and S2 of the first LED Del1.

The first LED Del1 has a circle shape in a plan view. The first surface S1 of the first LED Del1 is disposed under the step difference in a cross-sectional view and has a fan (circular sector) shape in a plan view. The second surface S2 of the first LED Del1 is disposed over the step difference in a cross-sectional view. The first surface S1 of a fan shape has a first central angle a1 and a first area A1.

In another embodiment, the first LED Del1 may have a polygon shape or an ellipse shape in a plan view.

The first protruding portion 226a protruding toward the first assembly groove 212a has a fan shape of the first central angle a1 and the first area A1.

As a result, the first LED Del1 is stably assembled to the first assembly groove 212a.

In FIGS. 10A and 10B, a top surface of a second LED Del2 in a second subpixel of a display device according to a second embodiment of the present disclosure includes a first surface S1, referred to as a mesa region, having a first electrode 168 and a second surface S2 having a second electrode 170 and disposed higher than the first surface S1.

A second assembly groove 212b of the assembly substrate 210 is defined as a space surrounded by a sidewall 226 and has a shape corresponding to the first and second surfaces S1 and S2 of the second LED Del2. The sidewall 226 of the second assembly groove 212b has a second protruding portion 226b extending from an inner surface thereof and corresponding to the first surface S1 and a step difference between the first and second surfaces S1 and S2 of the second LED Del2.

The second LED Del2 has a circle shape in a plan view. The first surface S1 of the second LED Del2 is disposed under the step difference in a cross-sectional view and has a fan (circular sector) shape in a plan view. The second surface S2 of the second LED Del2 is disposed over the step difference in a cross-sectional view. The first surface S1 of a fan shape has a second central angle a2 greater than the first central angle a1 and a second area A2 greater than the first area A1.

In another embodiment, the second LED Del2 may have a polygon shape or an ellipse shape in a plan view.

The second protruding portion 226b protruding toward the second assembly groove 212b has a fan shape of the second central angle a2 and the second area A2.

As a result, the second LED Del2 is stably assembled to the second assembly groove 212b.

In FIGS. 11A and 11B, a top surface of a third LED Del3 in a third subpixel of a display device according to a second embodiment of the present disclosure includes a first surface S1, referred to as a mesa region, having a first electrode 168 and a second surface S2 having a second electrode 170 and disposed higher than the first surface S1.

A third assembly groove 212c of the assembly substrate 210 is defined as a space surrounded by a sidewall 226 and has a shape corresponding to the first and second surfaces S1 and S2 of the third LED Del3. The sidewall 226 of the third assembly groove 212c has a third protruding portion 226c extending from an inner surface thereof and corresponding to the first surface S1 and a step difference between the first and second surfaces S1 and S2 of the third LED Del3.

The third LED Del3 has a circle shape in a plan view. The first surface S1 of the third LED Del3 is disposed under the step difference in a cross-sectional view and has a fan (circular sector) shape in a plan view. The second surface S2 of the third LED Del3 is disposed over the step difference in a cross-sectional view. The first surface S1 of a fan shape has a third central angle a3 greater than the second central angle a2 and a third area A3 greater than the second area A2.

In another embodiment, the third LED Del3 may have a polygon shape or an ellipse shape in a plan view.

The third protruding portion 226c protruding toward the third assembly groove 212c has a fan shape of the third central angle a3 and the third area A3.

As a result, the third LED Del3 is stably assembled to the third assembly groove 212c.

In FIGS. 9C and 9D, when the second and third LEDs Del2 and Del3 having the second and third central angles a2 and a3 that are greater than the first central angle a1 of the first protruding portion 226a and having the second and third areas A2 and A3 greater than the first area A1 of the first protruding portion 226a are inserted into the first assembly groove 212a, the magnetic force becomes greater than the electric force due to an abnormal assembly. As a result, the second and third LEDs Del2 and Del3 are not assembled to and easily escape from the first assembly groove 212a.

In FIG. 10C, when the first LED Del1 having the first central angle a1 smaller than the second central angle a2 of the second protruding portion 226b and having the first area A1 smaller than the second area A2 of the second protruding portion 226b is inserted into the second assembly groove 212b, the first LED Del1 does not contact the second assembly groove 212b due to the second protruding portion 226b. As a result, the first LED Del1 is not assembled to and easily escapes from the second assembly groove 212b.

In FIG. 10D, when the third LED Del3 having the third central angle a3 greater than the second central angle a2 of the second protruding portion 226b and having the third area A3 greater than the second area A2 of the second protruding portion 226b is inserted into the second assembly groove 212b, the magnetic force becomes greater than the electric force due to an abnormal assembly. As a result, the third LED Del3 is not assembled to and easily escapes from the second assembly groove 212b.

In FIGS. 11C and 11D, when the first and second LEDs Del1 and Del2 having the first and second central angles a1 and a2 smaller than the third central angle a3 of the third protruding portion 226c and having the first and second areas A1 and A2 smaller than the third area A3 of the third protruding portion 226c are inserted into the third assembly groove 212c, the first and second LEDs Del1 and Del2 do not contact the third assembly groove 212c due to the third protruding portion 226c. As a result, the first and second LEDs Del1 and Del2 are not assembled to and easily escape from the third assembly groove 212c.

In the second embodiment, since a dry etching step for forming the sidewall 226 having the assembly groove 212 a of a circle shape of a diameter of about 12 μm has a process margin of about ±2 μm with respect to one side of an arc, the first, second and third central angle a1, a2, and a3 for a sequential color mixture assembly of the LEDs Del may be determined to have a difference equal to or greater than about 19.1 degrees obtained by converting the process margin into an angle.

For example, the first, second and third central angles a1, a2 and a3 may be about 50 degrees, about 90 degrees and about 130 degrees, respectively.

In the display device according to a second embodiment of the present disclosure, the first surfaces (mesa region) S1 of the first, second and third LEDs Del1, Del2 and Del3 are formed to have the first, second and third central angles a1, a2 and a3 different from each other and the first, second and third areas A1, A2 and A3 different from each other, and the first, second and third protruding portions 226a, 226b and 226c of the first, second and third assembly grooves 212a, 212b and 212c are formed to have the first, second and third central angles a1, a2 and a3 different from each other and the first, second and third areas A1, A2 and A3 different from each other. As a result, an exclusivity (distinguishability) between the first, second and third LEDs Del1, Del2 and Del3 is improved, and a color mixture due to an abnormal assembly of the first, second and third LEDs Del1, Del2 and Del3 is prevented to obtain a high resolution.

Although the first, second and third colors of the first, second and third LEDs Del1, Del2 and Del3 exemplarily correspond to red, green and blue, respectively, in the second embodiment, the first, second and third colors may correspond to green, blue and red, respectively, or blue, red and green, respectively, in another embodiment. Alternatively, the first, second and third colors may correspond to different three colors, respectively, in another embodiment.

Consequently, in the display device according to the present disclosure, a color mixture is prevented or at least reduced and a fabrication process is optimized by changing a depth and an area of a mesa region. Further, a simultaneous assembly technology is applied to a relatively high resolution by forming the mesa regions of the red, green and blue light emitting diodes with the different depths or the different areas.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

What is claimed is:

1. A display device, comprising:
a display panel;
a plurality of gate lines and a plurality of data lines in the display panel, the plurality of gate lines and the plurality of data lines crossing each other to define a first subpixel, a second subpixel, and a third subpixel;
a transistor in each of the first subpixel, the second subpixel, and the third subpixel and connected to the plurality of gate lines and the plurality of data lines; and
a first light emitting diode, a second light emitting diode, and a third light emitting diode in the first subpixel, the second subpixel, and the third subpixel, respectively, and connected to the transistor,
wherein a top surface of each of the first light emitting diode, the second light emitting diode, and the third light emitting diode includes a first surface under a step difference in a cross-sectional view of the display device and a second surface over the step difference in the cross-sectional view, and
wherein first surfaces of the first light emitting diode, the second light emitting diode, and third light emitting diode have one of depths different from each other and areas different from each other.

2. The display device of claim 1, wherein the first surfaces of the first light emitting diode, the second light emitting diode, and the third light emitting diode have a first depth, a second depth, and a third depth, respectively, from the second surface, and
wherein the second depth is greater than the first depth and is smaller than the third depth.

3. The display device of claim 1, wherein the first surfaces of the first light emitting diode, the second light emitting diode, and the third light emitting diode have a first area, a second area, and a third area, respectively, and
wherein the second area is greater than the first area and is smaller than the third area.

4. The display device of claim 3, wherein the first surfaces of the first light emitting diode, the second light emitting diode, and the third light emitting diode have a first central angle, a second central angle, and a third central angle, respectively, and
wherein the second central angle is greater than the first central angle and is smaller than the third central angle.

5. The display device of claim 1, wherein each of the first light emitting diode, the second light emitting diode, and the third light emitting diode has one of a polygon shape, an ellipse shape, or a circle shape in a plan view of the display device.

6. The display device of claim 1, wherein each of the first light emitting diode, the second light emitting diode, and third light emitting diode comprises:
a first semiconductor layer;
an active layer on a first portion of the first semiconductor layer;
a second semiconductor layer on the active layer;
a first electrode on the second semiconductor layer; and
a second electrode on a second portion of the first semiconductor layer.

7. The display device of claim 6, wherein the first electrode and the second electrode are on the first surface and the second surface, respectively.

8. A method of fabricating a display device, comprising:
assembling a first light emitting diode, a second light emitting diode, and a third light emitting diode in a first assembly groove, a second assembly groove, and a third assembly groove, respectively, of an assembly substrate; and
transferring the first light emitting diode, the second light emitting diode, and the third light emitting diode to a display panel by disposing the assembly substrate having the first light emitting diode, the second light emitting diode, and the third light emitting diode over the display panel,
wherein a top surface of each of the first light emitting diode, the second light emitting diode, and the third light emitting diode includes a first surface under a step difference in a cross-sectional view of the display device and a second surface over the step difference in the cross-sectional view,
wherein first surfaces of the first light emitting diode, the second light emitting diode, and the third light emitting diode have one of depths different from each other and areas different from each other, and
wherein the first assembly groove, the second assembly groove, and the third assembly groove have a first protruding portion, a second protruding portion, and a third protruding portion, respectively, corresponding to the first surfaces of the first light emitting diode, the second light emitting diode, and the third light emitting diode.

9. The method of claim 8, wherein the first surfaces of the first light emitting diode, the second light emitting diode, and the third light emitting diode have a first depth, a second depth, and a third depth, respectively, from the second surface,
wherein the second depth is greater than the first depth and is smaller than the third depth, and
wherein the first protruding portion, the second protruding portion, and the third protruding portion have a first thickness, a second thickness, and a third thickness, respectively, and the first thickness, the second thickness, and the third thickness are a same as the first depth, the second depth, and the third depth, respectively.

10. The method of claim 8, wherein the first surfaces of the first light emitting diode, the second light emitting diode, and the third light emitting diode have a first area, a second area, and a third area, respectively,
wherein the second area is greater than the first area and is smaller than the third area, and
wherein the first protruding portion, the second protruding portion, and the third protruding portion have the first area, the second area, and the third area, respectively.
